(19) United States
(12) Patent Application Publication
(10) Pub. No.: US 2025/0374823 A1
(43) Pub. Date: Dec. 4, 2025

(54) TWO-DIMENSIONAL ORGANIC/INORGANIC HETEROJUNCTION PHOTODETECTOR AND PREPARATION METHOD THEREOF

(71) Applicant: NANJING UNIVERSITY OF POSTS AND TELECOMMUNICATIONS, Nanjing (CN)

(72) Inventors: Huijuan ZHAO, Nanjing (CN); Xiaohan GUO, Nanjing (CN); Li GAO, Nanjing (CN); Zemin TANG, Nanjing (CN)

(73) Assignee: NANJING UNIVERSITY OF POSTS AND TELECOMMUNICATIONS, Nanjing (CN)

(21) Appl. No.: 19/306,284

(22) Filed: Aug. 21, 2025

Related U.S. Application Data
(63) Continuation of application No. PCT/CN2025/079508, filed on Feb. 27, 2025.

(30) Foreign Application Priority Data
Mar. 7, 2024 (CN) 202410257498.3

(51) Int. Cl. H10K 85/60; H10K 30/10; H10K 30/60; H10K 71/16

(52) U.S. Cl. CPC H10K 85/621; H10K 30/10; H10K 30/60; H10K 71/164

(57) ABSTRACT

A two-dimensional organic/inorganic heterojunction photodetector and a preparation method thereof belongs to the technical field of photoelectric devices. A few layers of two-dimensional materials are transferred to a substrate as a base material by a mechanical peeling method. A few layers of two-dimensional alloy materials are transferred to one side of the two-dimensional materials on the base material by polydimethylsiloxane (PDMS). Then, the base material is put into a tube furnace. A single organic molecular layer is epitaxially grown on the two-dimensional alloy material by controlling the heating temperature and time to form a heterojunction. Finally, a gold thin film is transferred to the organic molecular layer, so that a photodetector is manufactured. The heterojunctions formed by Van der Waals have fewer defects, which can enhance light absorption without causing carrier capture, enabling photodetectors possesses excellent detection capability, large light absorption, and enhanced photoconductivity.

### CROSS-REFERENCE TO RELATED APPLICATIONS

This application is a continuation of International Application No. PCT/CN2025/079508, filed on Feb. 27, 2025, which claims priority to Chinese Patent Application No. 202410257498.3, filed on Mar. 7, 2024. All of the aforementioned applications are incorporated herein by reference in their entireties.

### TECHNICAL FIELD

The present disclosure relates to the technical field of photoelectric devices, and in particular to a two-dimensional organic/inorganic heterojunction photodetector and a preparation method thereof.

### BACKGROUND

A photodetector can convert an optical signal into an electrical signal, which is widely used in various fields of military and national economy and play an extremely important role. Nowadays, people have higher and higher requirements for high performance, wide spectrum and multi-band of a photodetector. Therefore, it is of great significance to develop and explore a photodetector based on a new material.

A two-dimensional material refers to a material in which an electron can only move freely on the two-dimensional nanometer scale (1 to 100 nm), such as a nano-film, a superlattice, a quantum well, etc. At present, the commonly used two-dimensional materials include graphene, molybdenum disulfide, boron nitride, etc. A two-dimensional material has been widely used in the photoelectric field in recent years because of the advantages such as no dangling bonds on the surface, adjustable band gaps, wide spectral detection and large-area preparation. Transition metal disulfide compounds (TMDCs) are ideal materials for Van der Waals interaction heterostructures because of the tunable band gap and deep light-matter interaction. However, the existence of internal defects in the TMDCs may hinder the generation and migration of photo-generated carriers, resulting in a delay in response speed.

It is found that the alloy based on the TMDCs not only has high carrier mobility, but also has low deep-level defect state density, which can effectively collect carriers and reduce unfavorable carrier trap. In addition, the low dark current of the TMDC alloy is beneficial to achieve a higher detection rate. In addition, compared with the traditional semiconductors of the TMDCs, an organic molecular crystal is low in dielectric constant and strong in absorption. Atomic layered inorganic semiconductors combined with molecular crystals may significantly adjust exciton coupling and produce new photoelectric properties. In order to overcome the limitation of weak absorption in the TMDCs on the performance of the photodetector, the number of molecular crystal layers can be accurately controlled to achieve complementary advantages, such as reducing the interface state combination, reducing Coulomb interaction, enhancing the light absorption effect and improving the interface carrier transfer.

However, in the prior art, when preparing an organic-inorganic heterojunction detector, a spin-coated thin film technology or a quantum dot structure is usually used. Harmful impurities may inevitably be introduced when the detector is prepared by using such methods, thus reducing the carrier mobility of the TMDCs. In addition, due to the insufficient spatial separation effect, the enhancement of the optical gain is also limited. Therefore, the preparation of high-quality hybrid heterostructures with clean interfaces has become an effective strategy to maintain the mobility of the TMDCs and further improve the detection sensitivity and the response speed of the photodetector.

Because the two-dimensional material layers are combined by covalent bonds, the Van der Waals force between layers is very weak. Therefore, the preparation of two-dimensional thin films can be achieved quickly by a mechanical peeling method. A polydimethylsiloxane (PDMS) peeling and transfer method is a method that uses a viscoelastic PDMS polymer film as a carrier transfer material. This method is simple and feasible, which involves no polymer spin coating. The whole process does not come into contact with any solution. Moreover, no more foreign impurities are introduced, and there are no special requirements for the substrate. Therefore, using this technology to transfer two-dimensional alloy materials can effectively control the decrease of carrier mobility of the TMDCs. It is worth noting that the two-dimensional material has a flat surface and no dangling bonds, which is an ideal Van der Waals epitaxial substrate material. The Van der Waals interaction between the two-dimensional material and the organic molecule is more conducive to the growth of high-performance organic films.

In the prior art of “Epitaxial Growth and Optical Properties of Two-Dimensional Organic Semiconductor Films”, it is mentioned that a vapor-phase epitaxial growth method based on the Van der Waals epitaxy technology can prepare organic films with ultra-high quality and ultra-high interface properties on different surface of the substrates, and at the same time, the thickness of the organic films can be accurately controlled at the monoatomic layer. It is pointed out in the article that a single layer of Me-PTCDI organic thin films prepared by a high-temperature epitaxial growth method has the advantages of high uniformity, high crystallinity, high stability, high luminous intensity and high quality. It is also pointed out in the article that the obtained high-quality single-crystal organic thin film and the high-interface organic-inorganic heterostructure will be used in high-performance organic photoelectric devices. However, only the film-making technology is explored, and no further applied research is made on the single layer of Me-PTCDI organic thin films prepared by a high-temperature epitaxial method. How to be combined with other substrates to obtain a high-performance photoelectric detector remains to be further explored by those skilled in the art.

### SUMMARY

The present disclosure aims to solve the problems existing in the prior art, provides a two-dimensional organic/inorganic heterojunction photodetector and discloses a specific preparation method thereof. The heterojunctions formed by Van der Waals epitaxial growth of the organic molecular layer and the two-dimensional alloy materials have fewer defects, which can enhance light absorption and may not cause carriers to be trapped. In this way, the prepared photodetector is high in detection rate and fast in response speed.

In order to achieve the above technical objectives, the present disclosure is achieved through the following technical solution: a preparation method of a two-dimensional organic/inorganic heterojunction photodetector, including the following steps:
(1) preprocessing a substrate, transferring a two-dimensional material to be transferred to a surface of the substrate by a mechanical peeling method, and selecting a two-dimensional material with a flat surface, a thickness of 5 to 20 nm and no residual glue bubbles to form a two-dimensional material/substrate structure;
(2) peeling off the two-dimensional alloy material on the blue film, and repeatedly pasting the two-dimensional alloy material with a controlled thickness of 0.7 to 20 nm to form a two-dimensional alloy material/blue film structure;
(3) adhering a polydimethylsiloxane (PDMS) film to a glass slide to obtain a PDMS/glass slide structure;
(4) transferring the two-dimensional alloy material to be transferred to the PDMS film by a mechanical peeling method to form a glass slide/PDMS/two-dimensional alloy material structure, and cutting off the redundant PDMS film centering on the two-dimensional alloy material to be transferred;
(5) fixing a glass slide with a two-dimensional alloy material in a substrate slot of a transfer platform, and placing the substrate on a sample holder of the transfer platform;
(6) by controlling an adhering and separation rate of the transfer platform, adhering the two-dimensional alloy material to one side of the two-dimensional material on the substrate after the two-dimensional alloy material is separated from the PDMS;
(7) placing an organic source material in the center of a tube furnace, placing the base material obtained in the previous step at the downstream position which is 1 to 20 cm away from the center, vacuumizing a chamber, controlling the heating temperature and time, and epitaxially growing a single layer of organic material crystals on the two-dimensional alloy material to obtain an organic material/two-dimensional alloy material/two-dimensional material/substrate structure; and
(8) transferring the prepared two gold films to two ends of one side of the organic material of the structure obtained in the previous step to complete the preparation.

Further, in Step (1), the two-dimensional material is hexagonal boron nitride.

Further, in Step (2), the two-dimensional alloy material is Mo_{0.1}W_{0.9}S₂ or Mo_{0.5}W_{0.5}S₂.

Further, the surface of the PDMS film is processed by UV Ozone before transferring the two-dimensional alloy material to the PDMS film.

Further, the two-dimensional alloy material transferred to the PDMS film is uniform and wrinkle-free with a thickness of 0.7 to 10 nm and 1 to 12 layers.

Further, in Step (6), when transferring the two-dimensional alloy material, the glass slide is lowered at a speed of 0.1 to 2 μm every 5 seconds to allow the two-dimensional alloy material to be adhered to one side of the two-dimensional material on a target substrate, maintaining the adhered state for 1 to 5 minutes, and then lifting the glass slide at a speed of 0.1 to 2 μm every 5 seconds to completely transfer the two-dimensional alloy material to the surface of the target substrate.

Further, in Step (7), the organic source material is N,N′-dimethyl-3,4,9,10-perylenetetracarboxylicdiimide (Me-PTCDI) or 3,4,9,10-perylene tetracarboxylic dianhydride (PTCDA).

Further, in Step (7), the tube furnace is heated to 200 to 280° C. to evaporate the organic source material to epitaxially grow a single layer of organic material crystals on the two-dimensional alloy material.

Further, in Step (8), the distance between two transferred strip-shaped gold films is 1 to 10 μm.

The two-dimensional organic/inorganic heterojunction photodetector prepared by the preparation method is provided with a two-dimensional material layer, a two-dimensional alloy material layer, a single layer of organic material crystals and a gold film on a substrate in sequence.

The present disclosure has the following beneficial effects.

Firstly, in the present disclosure, a photoelectric detector device with a simple structure is prepared by designing the Mo_{0.1}W_{0.9}S₂/Me-PTCDI heterojunction. The heterojunctions formed by Van der Waals epitaxial growth of the single organic molecular layer and the two-dimensional alloy materials have fewer defects, which can enhance light absorption and may not cause carriers to be trapped. Compared with traditional photoelectric detectors, the photoelectric detector prepared in the present disclosure is excellent in detection ability, large in light absorption and photoconductive gain, fast in response speed, and capable of achieving fast imaging with a high frame rate in weak light, which has a broad application prospect in the imaging field.

Secondly, in the present disclosure, two-dimensional alloy materials are used to prepare a heterojunction. Compared with traditional transition metal disulfide compounds, the alloy based on two-dimensional materials has lower deep-level defect state density, so that carriers may not be trapped by deep-level defects and may not hinder the generation and migration of photo-generated carriers, and the finally prepared photoelectric device has lower dark current and faster response speed.

Thirdly, in the present disclosure, an organic molecular layer is constructed on the surface of a two-dimensional alloy material layer by an epitaxial growth method. The organic molecular layer of Me-PTCDI with different layer thicknesses have different aggregation states. The aggregation state of a single layer of Me-PTCDI has strong light absorption and charge transfer properties, which can effectively improve the photocurrent of the photodetector and improve the responsivity and the detection rate.

Fourthly, the gold electrode on the photodetector prepared in the present disclosure is in contact with the heterojunction Van der Waals. The transfer contact form may not cause adverse doping to the heterojunction, may ensure good contact, and may not change the properties of the heterojunction.

Fifthly, in the present disclosure, the transfer platform is used to transfer the two-dimensional alloy material, so that the two-dimensional alloy material can be accurately transferred to any position of the target substrate. The stress is uniform in the transfer process, and no new wrinkles may be generated.

Sixthly, in the present disclosure, UV Ozone is used to preprocess the PDMS film, which can weaken the viscosity of the PDMS and reduce the adsorption of impurities on the surface of the material. After the two-dimensional alloy material is successfully transferred, the residual glue on the surface of the transferred two-dimensional alloy material can be greatly reduced.

Lastly, the heterojunction photodetector disclosed in the present disclosure is simple in preparation process and low in preparation cost, and is expected to be a feasible choice for low-cost and functional photoelectric detection or neuromorphic application in the future, thus providing new ideas for the development of corresponding fields.

### BRIEF DESCRIPTION OF THE DRAWINGS

FIG. 1 is a flow chart of the preparation of a two-dimensional organic/inorganic heterojunction photodetector.

FIG. 2 is a microscope photograph of an Me-PTCDI/Mo_{0.1}W_{0.9}S₂ heterojunction prepared in Embodiment 1.

FIG. 3 is a PL fluorescence photograph of an Me-PTCDI/Mo_{0.1}W_{0.9}S₂ heterojunction prepared in Embodiment 1.

FIG. 4 is a PL spectrum data of a mixed heterojunction, an Me-PTCDI organic source material and a Mo_{0.1}W_{0.9}S₂ two-dimensional alloy material prepared in Embodiment 1.

FIG. 5 is an optical response test diagram of a two-dimensional organic/inorganic heterojunction photodetector prepared in Embodiment 1.

FIG. 6 is a microscope photograph and a PL fluorescence photograph of an Me-PTCDI/Mo_{0.1}W_{0.9}S₂ heterojunction prepared in Embodiment 2.

FIG. 7 is an optical response test diagram of a two-dimensional organic/inorganic heterojunction photodetector prepared in Embodiment 2.

FIG. 8 is a comparison diagram of detection rates of a photodetector prepared in Embodiment 1, a photodetector prepared in Embodiment 2 and a two-dimensional organic photodetector prepared based on Mo_{0.1}W_{0.9}S₂.

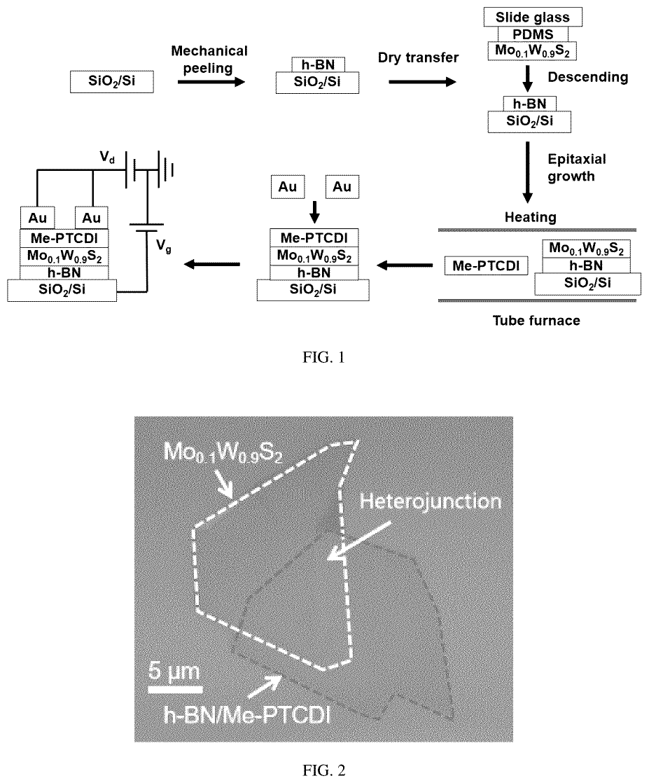

### DETAILED DESCRIPTION OF THE EMBODIMENTS

The following embodiments further illustrate the content of the present disclosure, but should not be construed as limiting the present disclosure. Modifications and substitutions made to the methods, steps or conditions of the present disclosure fall within the scope of the present disclosure without departing from the essence of the present disclosure.

### Embodiment 1: Preparation of a Two-Dimensional Organic/Inorganic Heterojunction Photodetector

Step (1), a silicon (having a thickness of 500 μm)/silicon oxide ((having a thickness of 275 nm) substrate are preprocessed (cleaning the surface with propanol after wafer cutting, then cleaning the propanol on the surface with deionized water, and drying the substrate with a nitrogen gun) to obtain a silicon-based substrate with a clean surface. A layered sample is peeled off from a hexagonal boron nitride (h-BN) bulk crystal with an adhesive tape by a mechanical peeling method, and then is transferred to the surface of the silicon-based substrate. The sample is observed through an optical microscope. h-BN with a flat surface, a thickness of 10 nm and no residual glue bubbles is selected to obtain the h-BN/substrate structure.

Step (2), the two-dimensional alloy material Mo_{0.1}W_{0.9}S₂ is peeled off on the blue film, and is repeatedly pasted, so that the thickness is up to about 20 nm, thus forming a Mo_{0.1}W_{0.9}S₂/blue film.

Step (3), the PDMS is cut into small pieces of 0.5 cm*2 cm. The film on its surface is peeled off, and is attached to the glass slide. The surface of the PDMS is processed with the UV Ozone, and then the blue film/two-dimensional alloy material is repeatedly pasted. Mo_{0.1}W_{0.9}S₂ on the blue film is transferred to the PDMS. A few layers of uniform and wrinkle-free Mo_{0.1}W_{0.9}S₂ (the number of layers of two-dimensional alloy materials is 10, and the thickness is 8 nm) is found under the microscope. The PDMS film is cut into squares with the size of 0.3 cm*0.3 cm with a blade around the transferred Mo_{0.1}W_{0.9}S₂ (after cutting off the redundant film, a certain width should be reserved from the material boundary, so that the two-dimensional alloy material should be in the center of the cut film as much as possible to facilitate the later transfer).

Step (4), on the transfer platform (the transfer platform has a function of finding Mo_{0.1}W_{0.9}S₂ previously observed under the microscope and is aligned with the substrate to be transferred, the glass slide with a two-dimensional alloy material is fixed in the substrate slot of the transfer platform, the silicon-based substrate is adsorbed on the sample holder of the transfer platform, the transfer platform can slowly ascend and descend, the minimum distance of ascending and descending is adjusted to be 0.5 μm, and the two-dimensional alloy material can be attached to the surface of the substrate slowly), first, the transferred Mo_{0.1}W_{0.9}S₂ is found, and is aligned with the h-BN/substrate structure to be transferred. In the transfer process, the adhering process is performed at a constant speed, descending at a rate of 0.5 μm every 5 seconds. After complete adhering, the adhering state is maintained for 1 minute, and then the separation is performed at a constant speed, ascending at a speed of 0.5 μm every 5 seconds (to avoid tearing the material or leaving a large number of bubbles and residual glue due to rapid separation), so as to obtain the Mo_{0.1}W_{0.9}S₂/h-BN/substrate structure.

Step (5), the organic source material of N,N′-dimethyl-3,4,9,10-perylenetetracarboxylicdiimide (Me-PTCDI) is put into a quartz boat, and the organic source material and the Mo_{0.1}W_{0.9}S₂/h-BN/substrate structure are put into a tube furnace to heat both sides of the center. The Me-PTCDI is placed in the center of the furnace, and the Mo_{0.1}W_{0.9}S₂/h-BN/substrate structure is put at the downstream position which is 3 cm away from the center. After vacuumizing the chamber for about 1 Pa, the furnace is heated to 220° C. to evaporate Me-PTCDI. A single layer of Me-PTCDI crystal starts to grow on the two-dimensional alloy material layer to obtain the Me-PTCDI/Mo_{0.1}W_{0.9}S₂/h-BN/substrate structure.

Step (6), the silicon wafer is adhered to a copper grid of 200 meshes, and is put into a high-vacuum electron beam evaporation coating instrument. Gold with a thickness of 120 nm is evaporated. The copper grid is taken off. The gold film is cut into a strip-shaped film of 600 μm×70 μm by using a fine needle with a tip diameter of 1 μm.

Step (7), on the Me-PTCDI/Mo0.1W0.9S2/h-BN/substrate structure, the strip-shaped gold film prepared in the previous step is transferred to both ends of one side of the organic material layer by using a fine needle by using a fine needle with a tip diameter of 15 μm, and the distance between the transferred two strip-shaped gold films is 3 μm.

FIG. 2 is a microscopic photograph of a single-layer Me-PTCDI (ML Me-PTCDI)/few-layer Mo_{0.1}W_{0.9}S₂ (FL Mo_{0.1}W_{0.9}S₂) heterojunction prepared in this embodiment. After a few layers of h-BN is transferred to a silicon-based substrate by a mechanical peeling method, a few layers of Mo_{0.1}W_{0.9}S₂ is transferred to the h-BN by the PDMS, and then a single layer of organic materials is epitaxially grown on a few layers of Mo_{0.1}W_{0.9}S₂ to obtain a heterojunction.

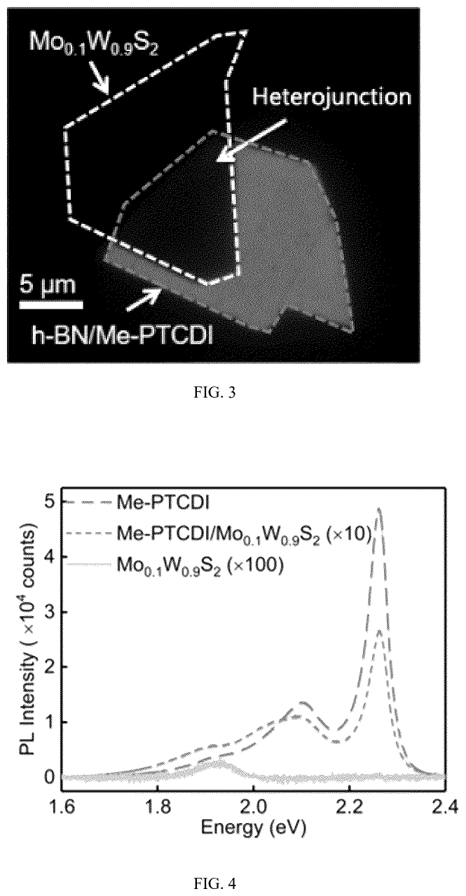

FIG. 3 is a PL fluorescence photograph of a hybrid heterojunction prepared in this embodiment. According to the observation through the PL fluorescence microscope, it is known that a single layer of Me-PTCDI on the h-BN shows uniform green luminescence. No green fluorescence is observed on Mo_{0.1}W_{0.9}S₂ because of the charge transfer in the heterojunction, which results in fluorescence quenching.

FIG. 4 is PL spectrum data of a mixed heterojunction, a Me-PTCDI organic source material and a Mo_{0.1}W_{0.9}S₂ two-dimensional alloy material prepared in this embodiment. It can be seen from the PL spectrum that at 2.26 eV, there are narrow peaks in the Me-PTCDI and the heterojunction, and the PL intensity of the heterojunction is about 95% lower than that of the Me-PTCDI. Excitons generated in the Me-PTCDI dissociate at the interface of the heterojunction, the charge is transferred to Mo_{0.1}W_{0.9}S₂, and the fluorescence of the single layer of Me-PTCDI is quenched.

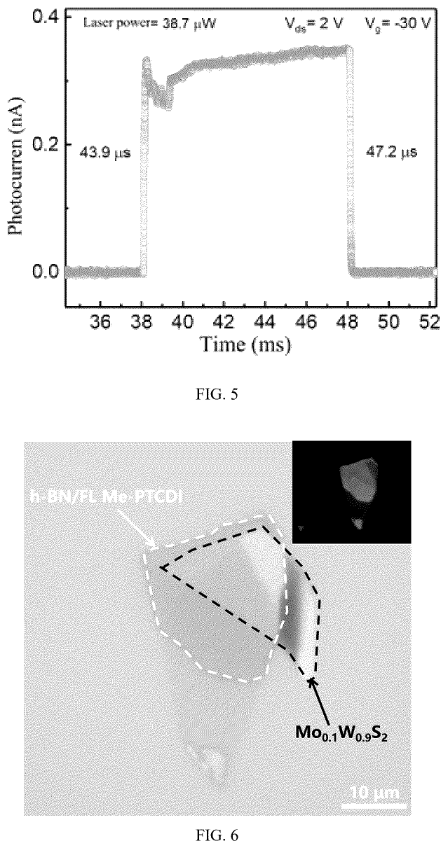

FIG. 5 is an optical response test diagram of a two-dimensional organic/inorganic heterojunction photodetector prepared in this embodiment. The increased current after illumination is mainly contributed by photo-generated carriers. At this time, the response time of ascending and descending is 43.9 μs and 47.2 μs, respectively. The response speed is fast.

### Embodiment 2: Preparation of a Two-Dimensional Organic/Inorganic Heterojunction Photodetector

Step (1), a silicon (having a thickness of 500 μm)/silicon oxide ((having a thickness of 275 nm) substrate are preprocessed (cleaning the surface with propanol after wafer cutting, then cleaning the propanol on the surface with deionized water, and drying the substrate with a nitrogen gun) to obtain a silicon-based substrate with a clean surface. A layered sample is peeled off from a hexagonal boron nitride (h-BN) bulk crystal with an adhesive tape by a mechanical peeling method, and then is transferred to the surface of the silicon-based substrate. The sample is observed through an optical microscope. h-BN with a flat surface, a thickness of 10 nm and no residual glue bubbles is selected to obtain the h-BN/substrate structure.

Step (2), the two-dimensional alloy material Mo_{0.1}W_{0.9}S₂ is peeled off on the blue film, and is repeatedly pasted, so that the thickness is up to about 20 nm, thus forming a Mo_{0.1}W_{0.9}S₂/blue film.

Step (3), the PDMS is cut into small pieces of 0.5 cm*2 cm. The film on its surface is peeled off, and is attached to the glass slide. The surface of the PDMS is processed with the UV Ozone, and then the blue film/two-dimensional alloy material is repeatedly pasted. Mo_{0.1}W_{0.9}S₂ on the blue film is transferred to the PDMS. A few layers of uniform and wrinkle-free Mo_{0.1}W_{0.9}S₂ is found under the microscope. The PDMS film is cut into squares with the size of 0.3 cm*0.3 cm with a blade around the transferred Mo_{0.1}W_{0.9}S₂ (after cutting off the redundant film, a certain width should be reserved from the material boundary, so that the two-dimensional alloy material should be in the center of the cut film as much as possible to facilitate the later transfer).

Step (4), on the transfer platform (the transfer platform has a function of finding Mo_{0.1}W_{0.9}S₂ previously observed under the microscope and is aligned with the substrate to be transferred, the glass slide with a two-dimensional alloy material is fixed in the substrate slot of the transfer platform, the silicon-based substrate is adsorbed on the sample holder of the transfer platform, the transfer platform can slowly ascend and descend, the minimum distance of ascending and descending is adjusted to be 0.5 μm, and the two-dimensional alloy material can be attached to the surface of the substrate slowly), first, the transferred Mo_{0.1}W_{0.9}S₂ is found, and is aligned with the h-BN/substrate structure to be transferred. In the transfer process, the adhering process is performed at a constant speed, descending at a rate of 0.5 μm every 5 seconds. After complete adhering, the adhering state is maintained for 1 minute, and then the separation is performed at a constant speed, ascending at a speed of 0.5 μm every 5 seconds (to avoid tearing the material or leaving a large number of bubbles and residual glue due to rapid separation), so as to obtain the two-dimensional material/h-BN/substrate structure.

Step (5), the organic source material of Me-PTCDI is put into a quartz boat, and the organic source material and the Mo_{0.1}W_{0.9}S₂/h-BN/substrate structure are put into a tube furnace to heat both sides of the center. The Me-PTCDI is placed in the center of the furnace, and the Mo_{0.1}W_{0.9}S₂/h-BN/substrate structure is put at the downstream position which is 3 cm away from the center. After vacuumizing the chamber for about 1 Pa, the furnace is heated to 250° C. to evaporate Me-PTCDI. A few layers of Me-PTCDI crystal (about 10 layers) grow on the two-dimensional alloy material layer to obtain the Me-PTCDI/Mo_{0.1}W_{0.9}S₂/h-BN/substrate structure.

Step (6), the silicon wafer is adhered to a copper grid of 200 meshes, and is put into a high-vacuum electron beam evaporation coating instrument. Gold with a thickness of 120 nm is evaporated. The copper grid is taken off. The gold film is cut into a strip-shaped film of 600 μm×70 μm by using a fine needle with a tip diameter of 1 μm.

Step (7), on the Me-PTCDI/Mo0.1W0.9S2/h-BN/substrate structure, the strip-shaped gold film prepared in the previous step is transferred to both ends of one side of the organic material layer by using a fine needle with a tip diameter of 15 μm, and the distance between the transferred two strip-shaped gold films is 4 μm.

The difference between this embodiment and Embodiment 1 is that in Embodiment 1, a single layer of organic thin films is epitaxially grown on the surface of the substrate on the Mo_{0.1}W_{0.9}S₂/h-BN substrate by a high-temperature method, while in this embodiment, 10 layers of organic materials are epitaxially grown on the surface of the substrate by the high-temperature method by adjusting the growth temperature and time.

FIG. 6 is a microscope photograph and a PL fluorescence photograph of a few-layer Me-PTCDI (FL Me-PTCDI)/few-layer Mo_{0.1}W_{0.9}S₂ (FL Mo_{0.1}W_{0.9}S₂) heterojunction prepared in this embodiment. In this embodiment, a few layers of h-BN are transferred to the silicon-based substrate by a mechanical peeling method. A few layers of Mo_{0.1}W_{0.9}S₂ are transferred to the h-BN by the PDMS, and a few layers of Me-PTCDI grow on the two-dimensional alloy material. The upper right illustration shows that under the PL fluorescence microscope, a few layers of organic materials emit red light, and the red light in the heterojunction region consisted of a few layers of Mo_{0.1}W_{0.9}S₂ and a few layers of Me-PTCDI is weakened but not completely quenched, mainly because the fluorescence of the thick layer of organic materials is strong and the charge transfer is not enough to completely quench the fluorescence. Therefore, a few layers of organic materials can still be observed to have fluorescence.

FIG. 7 is an optical response test diagram of a two-dimensional organic/inorganic heterojunction photodetector prepared in this embodiment. The increased current after illumination is mainly contributed by photo-generated carriers. At this time, the response time of ascending and descending is 555 ms and 362 ms, respectively. It can be inferred that growing a single layer of organic materials (ML Me-PTCDI) on a few layers of two-dimensional alloy materials (FL Mo_{0.1}W_{0.9}S₂) can further improve the photocurrent of the photodetector and improve the responsivity and the detection rate compared with growing a few layers of organic materials (FL Mo_{0.1}W_{0.9}S₂).

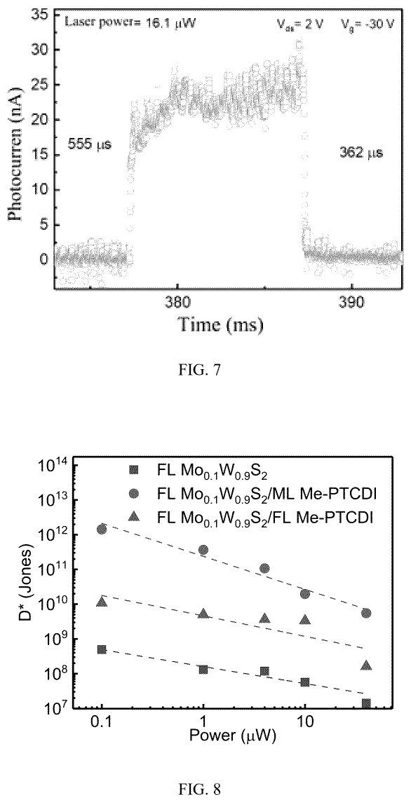

FIG. 8 is a comparison of optical power-dependent detection rates of a photodetector prepared in Embodiment 1, a photodetector prepared in Embodiment 2, and a two-dimensional organic photodetector prepared based on a few layers of Mo_{0.1}W_{0.9}S₂ (denoted as FL Mo_{0.1}W_{0.9}S₂, the photodetector is used as a comparison. When compared with the photodetector prepared in Embodiment 1, the difference is that the photodetector does not form an organic/inorganic heterojunction when being prepared. That is, the Me-PTCDI organic material layer is not grown on the two-dimensional alloy material layer. Other structures are the same as those of the photodetector in Embodiment 1). As can be seen from the figure, these three photodetectors show a similar trend that the detection rate changes with the optical power, indicating that Mo_{0.1}W_{0.9}S₂ dominates the optical response. However, the detection rate of the heterojunction photodetector based on a single organic molecular layer (denoted as FL Mo_{0.1}W_{0.9}S₂/ML Me-PTCDI) prepared in Embodiment 1 is the highest, because the heterojunction formed by s single layer of Me-PTCDI/a few layers of Mo_{0.1}W_{0.9}S₂ has a good charge transfer effect. Moreover, a few defects occur in the molecular layer, so that the responsivity is better than that of the heterojunction photodetector based on a few layers of organic molecular layers prepared in Embodiment 2 (denoted as FL Mo_{0.1}W_{0.9}S₂/FL Me-PTCDI). At the same time, the responsivity of the photodetector prepared in Embodiment 1 is significantly better than that of FL Mo_{0.1}W_{0.9}S₂, mainly because the heterojunction formed by epitaxial growth of a single organic molecular layer on a two-dimensional alloy material layer has almost no defects, which can enhance light absorption and may not cause carriers to be trapped, effectively improve the photocurrent of the photodetector, and improve the responsivity and the detection rate.

The basic principle, main features and advantages of the present disclosure have been shown and described above. However, the above is only a specific embodiment of the present disclosure, and the technical features of the present disclosure are not limited thereto. Any other embodiment obtained by those skilled in the art without departing from the technical solution of the present disclosure should be included in the patent scope of the present disclosure.

What is claimed is:

1. A preparation method of a two-dimensional organic/inorganic heterojunction photodetector, comprising following steps:
(1) preprocessing a substrate, transferring a two-dimensional material to be transferred to a surface of the substrate by a mechanical peeling method, and selecting a two-dimensional material with a flat surface, a thickness of 5 to 20 nm and no residual glue bubbles to form a two-dimensional material/substrate structure;
(2) peeling off the two-dimensional alloy material on the blue film, and repeatedly pasting the two-dimensional alloy material with a controlled thickness of 0.7 to 20 nm to form a two-dimensional alloy material/blue film structure;
(3) adhering a polydimethylsiloxane (PDMS) film to a glass slide to obtain a PDMS/glass slide structure;
(4) transferring the two-dimensional alloy material to be transferred to the PDMS film by a mechanical peeling method to form a glass slide/PDMS/two-dimensional alloy material structure, and cutting off the redundant PDMS film centering on the two-dimensional alloy material to be transferred;
(5) fixing a glass slide with a two-dimensional alloy material in a substrate slot of a transfer platform, and placing the substrate on a sample holder of the transfer platform;
(6) by controlling an adhering and separation rate of the transfer platform, adhering the two-dimensional alloy material to one side of the two-dimensional material on the substrate after the two-dimensional alloy material is separated from the PDMS;
(7) placing an organic source material in the center of a tube furnace, placing the base material obtained in the previous step at the downstream position which is 1 to 20 cm away from the center, vacuumizing a chamber, controlling the heating temperature and time, and epitaxially growing a single layer of organic material crystals on the two-dimensional alloy material to obtain an organic material/two-dimensional alloy material/two-dimensional material/substrate structure; and
(8) transferring the prepared two gold films to two ends of one side of the organic material of the structure obtained in the previous step to complete the preparation.

2. The preparation method of the two-dimensional organic/inorganic heterojunction photodetector according to claim 1, wherein in Step (1), the two-dimensional material is hexagonal boron nitride.

3. The preparation method of the two-dimensional organic/inorganic heterojunction photodetector according to claim 1, wherein in Step (2), the two-dimensional alloy material is Mo_{0.1}W_{0.9}S₂ or Mo_{0.5}W_{0.5}S₂.

4. The preparation method of the two-dimensional organic/inorganic heterojunction photodetector according to claim 1, wherein the surface of the PDMS film is processed by UV Ozone before transferring the two-dimensional alloy material to the PDMS film.

5. The preparation method of the two-dimensional organic/inorganic heterojunction photodetector according to claim 1, wherein the two-dimensional alloy material transferred to the PDMS film is uniform and wrinkle-free with a thickness of 0.7 to 10 nm and 1 to 12 layers.

6. The preparation method of the two-dimensional organic/inorganic heterojunction photodetector according to claim 1, wherein in Step (6), when transferring the two-dimensional alloy material, the glass slide is lowered at a speed of 0.1 to 2 μm every 5 seconds to allow the two-dimensional alloy material to be adhered to one side of the two-dimensional material on a target substrate, maintaining the adhered state for 1 to 5 minutes, and then lifting the glass slide at a speed of 0.1 to 2 μm every 5 seconds to completely transfer the two-dimensional alloy material to the surface of the target substrate.

7. The preparation method of the two-dimensional organic/inorganic heterojunction photodetector according to claim 1, wherein in Step (7), the organic source material is N,N′-dimethyl-3,4,9,10-perylenetetracarboxylicdiimide or 3,4,9,10-perylene tetracarboxylic dianhydride.

8. The preparation method of the two-dimensional organic/inorganic heterojunction photodetector according to claim 1, wherein in Step (7), the tube furnace is heated to 200 to 280° C. to evaporate the organic source material to epitaxially grow a single layer of organic material crystals on the two-dimensional alloy material.

9. The preparation method of the two-dimensional organic/inorganic heterojunction photodetector according to claim 1, wherein in Step (8), the distance between two transferred strip-shaped gold films is 1 to 10 μm.

10. A two-dimensional organic/inorganic heterojunction photodetector, which is prepared by the preparation method of the two-dimensional organic/inorganic heterojunction photodetector according to claim 1, wherein the photodetector is obtained by arranging a two-dimensional material layer, a two-dimensional alloy material layer, a single layer of organic material crystals and a gold film on a substrate in sequence.
